(19) United States
(12) Patent Application Publication
(10) Pub. No.: US 2014/0117390 A1
(43) Pub. Date: May 1, 2014

(54) LIGHT EMITTING DIODE PACKAGE

(71) Applicant: Advanced Optoelectronic Technology, Inc., Hsinchu Hsien 300 (TW)

(72) Inventors: HOU-TE LIN, Hsinchu (TW); PIN-CHUAN CHEN, Hsinchu (TW); LUNG-HSIN CHEN, Hsinchu (TW)

(73) Assignee: ADVANCED OPTOELECTRONIC TECHNOLOGY, INC., Hsinchu Hsien 303 (TW)

(21) Appl. No.: 13/900,559

(22) Filed: May 23, 2013

(30) Foreign Application Priority Data
Oct. 31, 2012 (CN) 2012104267830

(51) Int. Cl. H01L 33/60

(52) U.S. Cl. CPC H01L 33/60
USPC 257/98

(57) ABSTRACT

An LED package includes a first electrode and a second electrode electrically insulating from the first electrode, an LED chip, two electrically insulating connecting layers, and a reflector. Top surfaces of the first electrode and the second electrode are recessed to define a first receiving space and a second receiving space therein. The LED chip is mounted on the top surface of the first electrode and electrically connects the first electrode and the second electrode. The electrically insulating connecting layers are respectively received in the first receiving space and the second receiving space. The reflector is mounted on top surfaces of the connecting layers and enclosing the LED chip therein.

### BACKGROUND

1. Technical Field

The present disclosure relates to semiconductor devices and, more particularly, to a light emitting diode (LED) package.

2. Description of Related Art

A conventional LED package includes a substrate, a LED chip mounted on a top surface of the substrate, and a reflector mounted on the top surface of the substrate and enclosing the LED chip therein. The reflector is adhered to the substrate by glue arranged between a bottom end of the reflector and the top surface of the substrate. Therefore, a height of the LED package is increased. Thus, the LED package can not suitable for a thin type device again.

Accordingly, it is desirable to provide an LED package which can overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross sectional view of an LED package of a first embodiment of the present disclosure.

FIG. 2 is a cross sectional view of an LED package of a second embodiment of the present disclosure.

FIG. 3 is a cross sectional view of an LED package of a third embodiment of the present disclosure.

### DETAILED DESCRIPTION

Embodiments of an LED package will now be described in detail below and with reference to the drawings.

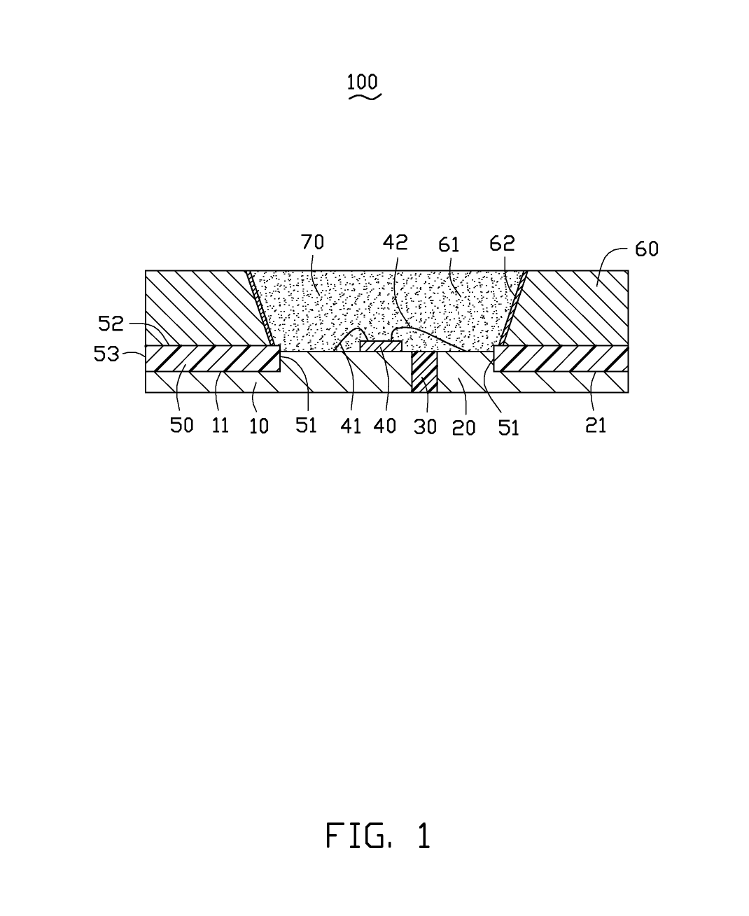

Referring to FIG. 1, an LED package 100 according to a first embodiment is shown. The LED package 100 includes a first electrode 10, a second electrode 20, a connector 30 connecting the first electrode 10 and the second electrode 20, an LED chip 40 mounted on the first electrode 10 and electrically connecting the first electrode 10 and the second electrode 20, two connecting layers 50 respectively formed on the first electrode 10 and the second electrode 20, a reflector 60 mounted on the connecting layers 50 and a packaging layer 70 filled in the reflector 60.

The first electrode 10 and the second electrode 20 are spaced from each other. A top surface of the first electrode 10 is coplanar and parallel to a top surface of the second electrode 20. A bottom surface of the first electrode 10 is coplanar and parallel to a bottom surface of the second electrode 20. An outer side of a top end of the first electrode 10 is recessed from the top surface to define a first receiving space 11 in the first electrode 10. An outer side of a top end of the second electrode 20 is recessed from the top surface to define a second receiving space 21 in the second electrode 20. A profile of the first receiving space 11 and the second receiving space 21 is L-shaped. In this embodiment, the first electrode 10 and the second electrode 20 are made of copper or chromium.

The connector 30 is electrically insulating and opposite sides thereof respectively connect inner sides of the top ends of the first electrode 10 and the second electrode 20. Top and bottom ends of the connector 30 are coplanar with the top surface and the bottom surface of the first electrode 10, respectively. The connector 30 is made of epoxy resin, plastic, silicone and so on.

The LED chip 40 is mounted on an inner end of the top surface of the first electrode 10. The chip 40 electrically connects the top surfaces of the first electrode 10 and the second electrode 20 by wires 41, 42.

Each connecting layer 50 is electrically insulating and made of polymer such as amanium. The connecting layers 50 are received in the first receiving space 11 and the second receiving space 21. The connecting layer 50 includes an inner surface 51, an outer surface 53 opposite to the inner surface 51, and a top surface 52 interconnecting the inner surface 51 and the outer surface 53. In this embodiment, when the connecting layers 50 are mounted on the first electrode 10 and the second electrode 20, bottom ends of the connecting layers 50 are received in the first receiving space 11 and the second receiving space 21, respectively and top ends of the connecting layers 50 are beyond the top surfaces of the first electrode 10 and the second electrode 20.

Specifically, the top surfaces 52 of the connecting layers 50 are located above the top surface of the first electrode 10 and the second electrode 20, the inner surfaces 51 abut inner edges of the first receiving space 11 and the second receiving space 21, and the outer surfaces 53 are coplanar with outer peripheries of the first electrode 10 and the second electrode 20. Top ends of the inner surfaces 51 are exposed. The LED chip 40 is arranged between the top ends of the inner surfaces 51. The top surfaces 52 of the connecting layers 50 are coplanar. A distance between the top surface 52 and the top surface of the first electrode 10 is less than or equal to 80 microns. Preferably, the distance between the top surface 52 and the top surface of the first electrode 10 is less than or equal to 40 microns.

The reflector 60 is a hollow tube. A bottom end of the reflector 60 is mounted on the top surfaces 52 of the connecting layers. An outer periphery of the reflector 60 is coplanar with the outer peripheries of the first electrode 10 and the second electrode 20. A through hole 61 is defined in a center of the reflector 60 to receive the packaging layer 70 therein. A bore diameter of the through hole 61 decreases from a top end away from the connecting layer 50 to a bottom end mounted on the connecting layer 50. The LED chip 40 is located a center of a bottom end of the through hole 61. An inner surface of the through hole 61 reflects light emitted from the LED chip 40 out from the reflector 60. A reflecting film 62 is formed on an inner surface of the through hole 60 to improve light outputting efficiency of the LED package 100. The reflecting film 62 is a metal film with a uniform thickness. The reflector 60 is metallic and has good heat dissipation performance.

The packaging layer 70 fills in the through hole 61 to encapsulate the LED chip 40 therein to protect the LED chip 40. The packaging layer 70 is made of glue. The glue is a pure silica gel or a mixture mixed by a pure silica gel and phosphor powder.

In this embodiment, because only the top end of the connecting layer 50 is beyond the top surface of the first electrode 10, a height of the LED package 100 is decreased relative to the conventional LED package. Thus, the LED package 100 can suitable for the thin type device.

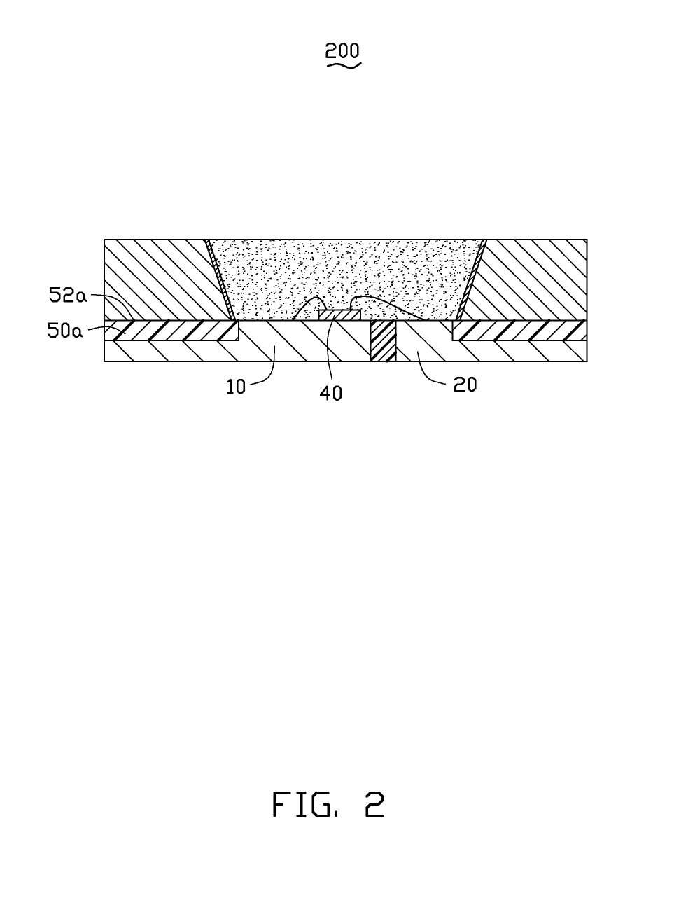

Referring to FIG. 2, an LED package 200 is similar to the LED package 100 of the first embodiment, and a difference therebetween is that whole of the connecting layer 50a are received in the first receiving space 11 and the second receiving space 21, and top surfaces 52a of the connecting layer 50a are coplanar with the top surfaces of the first electrode 10 and the second electrode 20.

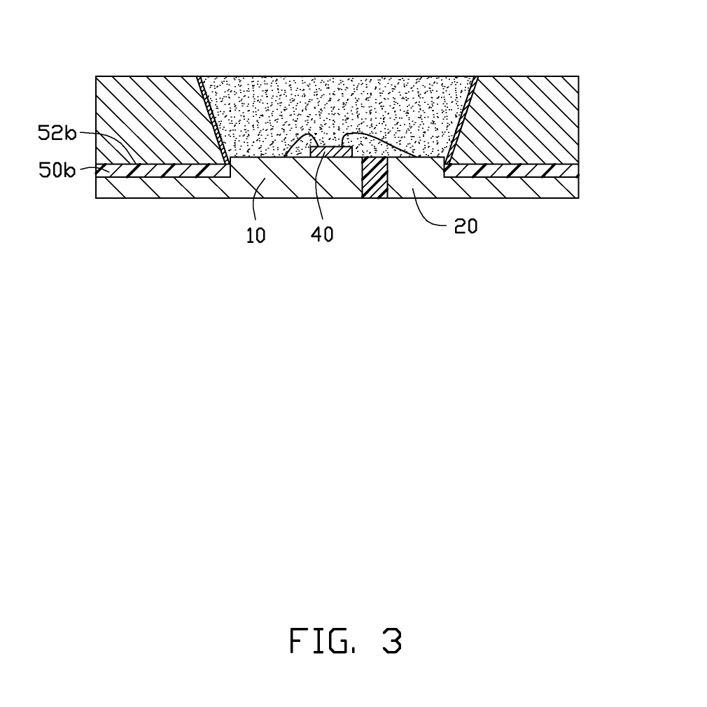

Referring to FIG. 3, an LED package 300 is similar to the LED package 100 of the first embodiment, and a difference therebetween is that whole of the connecting layer 50b are received in the first receiving space 11 and the second receiving space 21, and top surfaces 52b of the connecting layer 50b are below the top surfaces of the first electrode 10 and the second electrode 20. A distance between the top surface 52b of the connecting layer 50b and the top surface of the first electrode 10 is less than or equal to 40 microns.

Because whole of the connecting layers 50a and 50b are received in the receiving space 11 and the second receiving space 21, light emitted from the LED chip 40 is not absorbed by connecting layers 50a and 50b. Therefore, light extraction efficiency of the LED packages 200, 300 is improved.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED (light emitting diode) package, comprising:
a first electrode and a second electrode electrically insulating from the first electrode, top surfaces of the first electrode and the second electrode recessed to define a first receiving space and a second receiving space therein;
an LED chip mounted on the top surface of the first electrode and electrically connecting the first electrode and the second electrode;
two connecting layers respectively received in the first receiving space and the second receiving space, the connecting layers being electrically insulating; and
a reflector mounted on top surfaces of the connecting layers and enclosing the LED chip therein.

2. The LED package of claim 1, wherein bottom ends of the connecting layers are received in the first receiving space and the second space, and top ends of the connecting layers are beyond the top surfaces of the first electrode and the second electrode.

3. The LED package of claim 2, wherein the top surfaces of the connecting layers are coplanar and beyond the top surfaces of the first electrode and the second electrode.

4. The LED package of claim 3, wherein a distance between the top surface of the connecting layer and the top surface of the first electrode is less than or equal to 80 microns.

5. The LED package of claim 3, wherein a distance between the top surface of the connecting layer and the top surface of the first electrode is less than or equal to 40 microns.

6. The LED package of claim 1, wherein whole of the connecting layers are received in the first receiving space and the second receiving space.

7. The LED package of claim 6, wherein the top surfaces of the connecting layers are coplanar and coplanar with the top surfaces of the first electrode and the second electrode.

8. The LED package of claim 6, wherein the top surfaces of the connecting layers are coplanar and below the top surfaces of the first electrode and the second electrode.

9. The LED package of claim 8, wherein a distance between the top surface of the connecting layer and the top surface of the first electrode is less than or equal to 40 microns.

10. The LED package of claim 1, wherein the reflector is a hollow tube, a through hole is defined in a center of the reflector, and the LED chip is located in the through hole.

11. The LED package of claim 10, wherein a bore diameter of the through hole decreases from a top end away from the connecting layer to a bottom end mounted on the connecting layer.

12. The LED package of claim 10, wherein a reflecting film is formed on an inner surface of the through hole.

13. The LED package of claim 12, wherein the reflecting film is a metal film with a uniform thickness.

14. The LED package of claim 10, wherein the reflector is metallic.

15. The LED package of claim 10, wherein a packaging layer is filled in the through hole to encapsulate the LED chip therein.

16. The LED package of claim 1, wherein a connector is located between the first electrode and the second electrode and opposite sides thereof connect the first electrode and the second electrode.
